(19) United States
(12) Patent Application Publication
(10) Pub. No.: US 2006/0114140 A1
(43) Pub. Date: Jun. 1, 2006

(54) Two step flash analog to digital converter

(75) Inventor: Fu-Lung Hsueh, Hsinchu (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd.

(21) Appl. No.: 10/998,389

(22) Filed: Nov. 29, 2004

(51) Int. Cl. H03M 1/12

(52) U.S. Cl. 341/155

(57) ABSTRACT

This invention discloses a method for converting an analog signal to a digital signal as the following steps. A reference voltage range is divided into a plurality of reference levels. The analog signal is compared with the reference levels to generate first conversion bits. A reference voltage sub-range defined by a first value and a second value of the reference level is selected, wherein the voltage level of the analog signal is higher than the first value and lower than the second value. The reference voltage sub-range is divided into a plurality of reference sub-levels. The analog signal is compared with the reference sub-levels to generate second conversion bits. The digital signal representing the analog signal is generated based on the first-conversion bits and the second conversion bits.

### BACKGROUND

The present invention relates generally to semiconductor devices, and more particularly to the implementation of a two-step analog-to-digital converter.

Analog-to-digital converters (ADC) have existed for decades, and are instrumental in determining the quality and the speed of many electronic systems. One type of commonly-used ADC is the flash ADC. A flash ADC has many advantages. As an example, a flash ADC performs fast analog-to-digital conversions, has little intrinsic delays, and is easy to design. They are often used in high-load, high-availability electronic systems.

However, flash ADCs have disadvantages. As an example, flash ADCs consume more power than regular ADCs. As another example, flash ADCs require a larger component count than regular ADCs, and therefore require a larger physical footprint. In addition, because they inherently have lower resolutions, and require a higher input loading than regular ADCs, integrated circuit (IC) designers spend a huge amount of resources just to improve the performance-to-cost ratio. These disadvantages limit them to high frequency and expensive applications that typically cannot be addressed by other ADC types. For example, these applications include: real-time data acquisition, satellite communication, radar processing, sampling oscilloscopes, and high density disk drives.

Desirable in the art of flash analog-to-digital converter designs are improved designs that reduce the component count, physical size, input loading, power consumption, and cost.

### SUMMARY

This invention discloses a method and system for converting an analog signal to a digital signal using the following steps. The analog signal is compared with a plurality of reference levels dividing a reference voltage range to generate a first set of conversion bits indicating the reference level surpassed by the analog signal. A reference voltage sub-range defined by a first reference level and a second reference level is selected, wherein the analog signal has a voltage level higher than the first reference level and lower than the second reference level. The reference voltage sub-range is divided by a plurality of reference sub-levels. The analog signal is compared with the reference sub-levels to generate a second set of conversion bits indicating the reference sub-level surpassed by the analog signal. The digital signal representing the analog signal is generated based on the first set of conversion bits and the second set of conversion bits.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 presents a conventional 8-bit flash ADC.

FIG. 2 presents an 8-bit two-step ADC, in accordance with one embodiment of the present invention.

FIG. 3 presents a diagram showing an analog signal is compared with many reference voltage levels, in accordance with one embodiment of the present invention.

FIG. 4 presents diagrams illustrating a method for eliminating the noise effect in the first-step MSB conversion, in accordance with one embodiment of the present invention.

FIGS. 5A and 5B present a block diagram and a timing diagram of the first-step MSB conversion, in accordance with one embodiment of the present invention.

FIGS. 5C and 5D present a block diagram and a timing diagram of the second-step LSB conversion, in accordance with one embodiment of the present invention.

### DESCRIPTION

In one embodiment of the invention, a new flash ADC circuit is disclosed implementing a two-step ADC decoding method that uses a voltage shift in a first-step conversion. The voltage shift in the first-step conversion eliminates the noise effect on the conversion. A second-step conversion completes the two-step ADC decoding method by recovering an offset voltage applied in the first-step conversion. The two-step ADC decoding method, which uses a novel voltage shift method, reduces the component count of the ADC comparator, improves the input loading, increases input signal bandwidth, reduces chip size, and reduces power consumption.

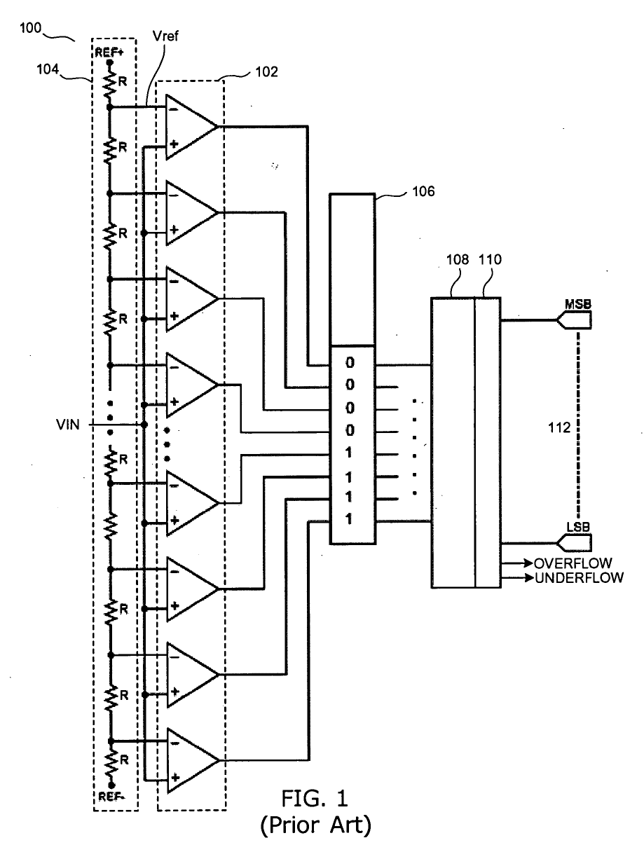

FIG. 1 presents a conventional 8-bit flash ADC 100. A conventional “n” bit flash ADC is comprised of 2^{N}−1 comparators with 2^{N}−1 different voltage levels. Therefore, the conventional 8-bit flash ADC 100 has 255 comparators utilizing 255 voltage levels that are required to produce eight digital outputs. A comparator array 102 contains the 255 comparators. The input analog signal V_{IN} is connected to one input line of each of the 255 comparators, while the other input of the comparator receives one of the 255 reference voltages. Each of the 255 reference voltages is generated by a reference resistor ladder 104. Each of the 255 comparators compares the V_{IN} signal to its specific reference voltage, and generates a high output when the V_{IN} signal is higher than the corresponding reference voltage. If the V_{IN} signal is less than the comparator's reference voltage, the comparator's output remains low. Each of the 255 comparator outputs is then sent to a thermo decoder 106, which generates a thermometer code. A thermometer code output is a sequence of the 255 bits in which the 255 bits are consecutively asserted, beginning from low signal voltage to high signal voltage level. The thermometer code generated by the comparators is then converted to a binary digital signal via a decoder 108. In this example, the decoder 108 consists of four 6-bit ROM decoders followed by a multiplexer 110 that selects the outputs, in order, from the LSB to the MSB, and outputs the bits as an 8-bit binary digital code 112 representing the binary value of the V_{IN} signal. In addition, an overflow signal is generated to indicate when the range of the conventional 8-bit flash ADC 100 is exceeded. Similarly, an underflow signal is generated to indicate when the input signal is below the lowest reference voltage.

Inherent in the design of the conventional 8-bit flash ADC 100 is the large number of input comparators (255 in this 8-bit example). The large number of comparators add a huge capacitive load to the V_{IN} signal, so much so that the input signal bandwidth is severely limited. The large number of comparators also consumes more power and requires a larger chip footprint. As such, the conventional 8-bit flash ADC 100 is both power-consuming and cost-ineffective.

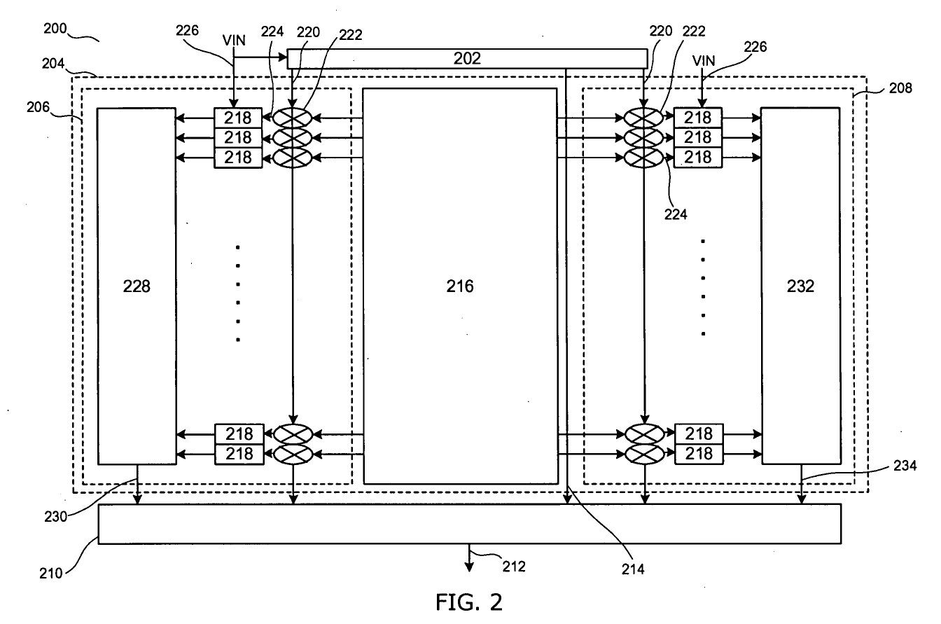

FIG. 2 presents an 8-bit two-step flash ADC 200 using a voltage shift in a first-step MSB conversion, in accordance with one embodiment of the present invention. This embodiment reduces the ADC noise effect on the first-step MSB conversion, and reduces the input comparator component count, thereby increasing the bandwidth of the input signal. The ADC 200 utilizes a 3-bit flash ADC 202 in the first-step MSB conversion, and a 6-bit flash ADC 204 in the second-step LSB conversion. The 3-bit flash ADC 202 is comprised of a total of 8 MSB bits (2^{X} bits, where X=3). The 6-bit flash ADC 204 is comprised of a total of 64 LSB bits (2^{Y} bits, where Y=6).

In the 8-bit two-step flash ADC 200, the 6-bit flash ADC 204 is shown with a block 206, which includes the upper 32 LSB bit comparators and their corresponding decoder 228, and a block 208, which includes the lower 32 LSB bit comparators and their corresponding decoder 232. The subsequent decoded data from the 3-bit flash ADC 202 and the 6-bit flash ADC 204 are fed to a multiplexer 210 to generate an 8-bit signal 212, which is the digital equivalent of the V_{IN} signal.

A total of 72 comparators (8 comparators for the 3-bit flash ADC 202 and 64 comparators for the 6-bit flash ADC 204) are required to implement the 8-bit two-step flash ADC 200. When compared to the 255 comparators required by the conventional 8-bit flash ADC 100, a significant reduction of component count (183 comparators=255−72) can be achieved. The two-step design reduces the ADC comparator component count, improves the input loading, increases the input signal bandwidth, reduces the required chip size, reduces power consumption, and hence reduces the ADC cost.

The first-step MSB conversion performed by the 3-bit flash ADC 202, which utilizes the full reference voltage range, provides a coarse decoding of the V_{IN} signal. The second-step LSB conversion performed by the 6-bit flash ADC 204 provides a much finer decoding of the V_{IN} signal, and uses the coarse decoding as a starting point for its decoding. The 6-bit flash ADC 204 utilizes only one-fourth of the full reference voltage range to achieve the finer decoding. When decoded data in both the first-step and the second-step conversions are combined, the 8-bit signal 212, which is an accurate digital representation of the V_{IN} signal, is generated.

A reference resistive ladder is utilized to provide precise reference voltages for each comparator of the 3-bit flash ADC 202 and the 6-bit flash ADC 204. The 3-bit flash ADC 202 requires 8 reference voltage inputs by a reference resistive ladder. The input analog signal, or the V_{IN} signal, is connected to one input line of each of the 8 comparators while the other input of the comparator receives one of the 8 reference voltages.

The 8 comparators compensate noise effects due to the conversion process by adding an offset voltage to the V_{REF} signal going to the comparator input. Each of the 8 comparators compares the V_{IN} signal to its specific reference voltage, and generates a high output when the V_{IN} signal is higher than its reference voltage. If V_{IN} signal is less than the comparator's reference voltage, the comparator's output remains low. The 3-bit flash ADC 202 comparator outputs are then decoded, and the 3 decoded digital bits of the ADC output are sent, via a line 214, to the multiplexer 212 to complete full analog-to-digital conversion.

A reference resistive ladder 216 is utilized to provide 64 precise reference voltages for 64 comparators 218 of the 6-bit flash ADC 204. The reference voltages generated from the reference resistive ladder 216 are selected via a line 220, by the decoded outputs of the 3-bit flash ADC 202, at a summing point 222. This summation is repeated for each of the comparators 218 before it is applied, as a comparator input 224, to each comparator. The V_{IN} signal is tied to another comparator input 226. The upper 32 LSBs are compared and decoded in a decoder 228, with the upper 6 LSBs sent to the multiplexer 210 via a line 230. The lower 32 LSBs are compared and decoded in a decoder 232, with the lower 6 LSBs sent to the multiplexer 210 via a line 234. The decoded data sent to the multiplexer 210 via the lines 214, 230 and 234 are used to generate the 8-bit digital 212, which is the digital equivalent of the V_{IN} signal.

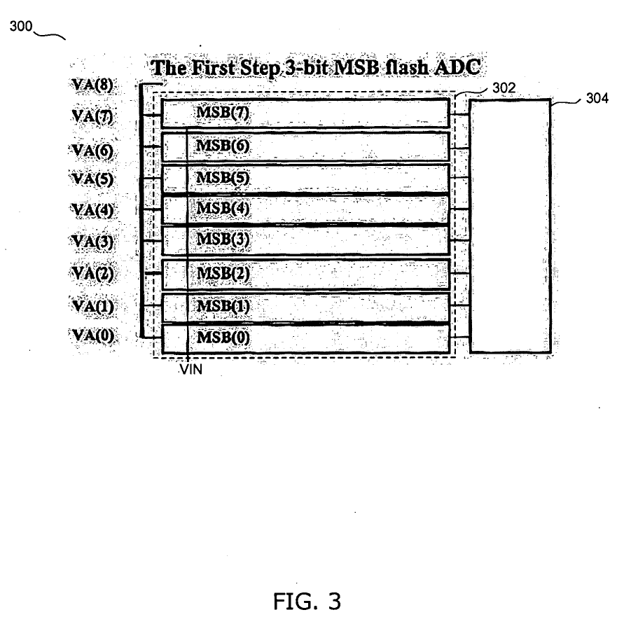

FIG. 3 presents a diagram 300 showing how the 3-bit flash ADC works in accordance with one embodiment of the present invention. The diagram 300 illustrates the reference voltage VA(0) through VA(8) divided equally across the eight MSBs, or MSB(0) through MSB(7), of the 3-bit flash ADC, which generates a 3-bit digital equivalent of the V_{IN} signal. A comparator array 302 contains 8 comparators. The V_{IN} signal is connected to one input line of each of the 8 comparators, while the other input of the comparator receives one of the 8 summed reference voltages. Each of the reference voltages is generated in a reference resistor ladder. The reference voltage VA(8) is tied to the overflow indicator circuitry, not shown, which indicates when the V_{IN} signal exceeds the maximum range of the ADC.

Each of the 8 comparators compares the V_{IN} signal to its specific summed reference voltage (VA0 through VA7) and generates a high output when the V_{IN} signal is higher than its reference voltage. If the V_{IN} signal is less than the comparator's reference voltage, the comparator's output remains low. Each of the 8 comparator outputs is sent to a thermo decoder 304 that generates a thermometer code. A thermometer code output is a sequence of the 8 bits in which the 8 bits are consecutively asserted, beginning with the low voltage level to high voltage level. The thermometer code generated by the comparators is then converted to a binary digital signal via the thermo decoder 304.

A table 1 shows the thermo-code output in the first-step MSB conversion, while a table 2 shows the reference voltage range in the second-step LSB conversion in accordance with one embodiment of the present invention. The second-step LSB conversion has a range of one-fourth of the full reference voltage. Therefore, for each of the 8 increments of MSB0 through MSB7, that is, from 10000000 to 11111111, the voltage range of the second-step LSB conversion increments by 2 analog reference voltage steps from VA0 through VA8. For example, for 1111000, the second-step LSB conversion has a voltage range of VA3 to VA5. This enables a finer decoding, or a more precise resolution when compared to the first-step MSB conversion.

TABLE 1

| | Comparator output states as input signals | | | | | | | |
|---|---|---|---|---|---|---|---|---|
| | increasing from 0 to a full range. | | | | | | | |
| MSB(7) | 0 | 0 | 0 | 0 | 0 | 0 | 0 | 1 |
| MSB(6) | 0 | 0 | 0 | 0 | 0 | 0 | 1 | 1 |
| MSB(5) | 0 | 0 | 0 | 0 | 0 | 1 | 1 | 1 |
| MSB(4) | 0 | 0 | 0 | 0 | 1 | 1 | 1 | 1 |
| MSB(3) | 0 | 0 | 0 | 1 | 1 | 1 | 1 | 1 |
| MSB(2) | 0 | 0 | 1 | 1 | 1 | 1 | 1 | 1 |
| MSB(1) | 0 | 1 | 1 | 1 | 1 | 1 | 1 | 1 |
| MSB(0) | 1 | 1 | 1 | 1 | 1 | 1 | 1 | 1 |

TABLE 2
Selected Voltage Range for 6-bit ADC

| | | | | | | | | |
|---|---|---|---|---|---|---|---|---|
| High | VA(2) | VA(3) | VA(4) | VA(5) | VA(6) | VA(7) | VA(8) | VA(8) |
| Low | VA(0) | VA(1) | VA(2) | VA(3) | VA(4) | VA(5) | VA(6) | VA(6) |

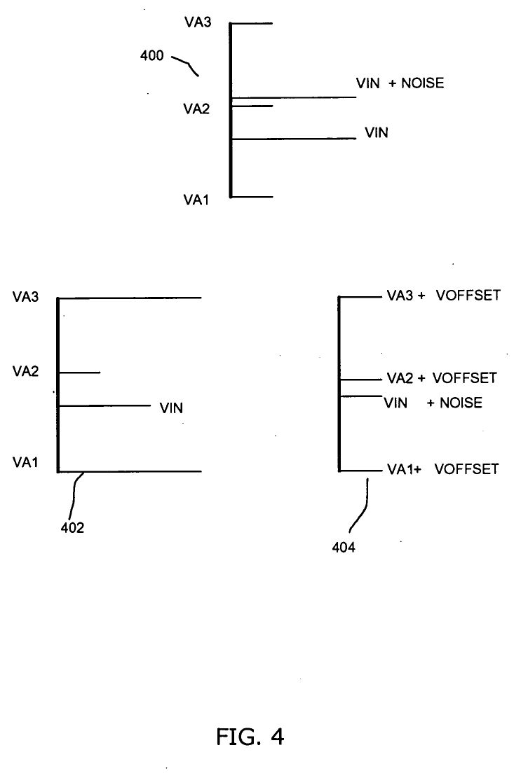

FIG. 4 presents diagrams 400, 402 and 404 illustrating the method of eliminating the noise effect in the first-step MSB conversion in accordance with one embodiment of the present invention. In the diagram 400, the V_{IN} signal is sampled by the first-step MSB conversion to be higher than VA1 but less than VA2. Consider this measurement to be the ideal case in which no noise is present. In this “no noise” case, the MSB output, based upon the table 306, is 11000000 (MSB0 to MSB7). However, in the more likely case of noise being present with the V_{IN} signal, it is possible that the V_{IN} signal with noise (V_{IN}+noise) causes the level to be above the VA2 reference voltage threshold, thereby producing an incorrect MSB output of 11100000.

As described earlier, a two-step conversion with offset voltage correction (or auto-zeroing in the MSB conversion) will eliminate this noise error. The diagram 402 shows the V_{IN} signal without noise located above VA1 but less than VA2, which is similar to the diagram 400. The diagram 404 shows the addition of an offset voltage (V_{OFFSET}) to the MSB reference voltage (VA1 through VA7) to eliminate the noise effect. In this case, the summation of the V_{IN} signal and noise (V_{IN}+noise) always falls below the summation of VA2 and the offset voltage (VA2+V_{OFFSET}). Therefore, the MSB output is the original ideal case output of 11000000.

Where the offset voltage is added to the MSB reference voltage, an additional MSB bit is used to calibrate the analog signal underestimated by the offset voltage. In this embodiment, the offset voltage may underestimate the analog signal by one reference voltage segment, if the analog signal is not or insignificantly interfered by noise. For example, if the MSB bits equal to 2, the reference voltage sub-range will incorrectly select the underestimated reference segment, and the second step conversion will produce an incorrect result. In this embodiment, an additional bit is used to make the MSB bits equal to 3. Here, a reference voltage sub-range includes two reference segments, that is the segment where the analog signal falls in, and the segment right below it, which is where the analog signal should have fallen in but for the noise interference. Thus, the second step conversion based on this reference voltage sub-range is able to calibrate this underestimation, and produces a correct result.

As discussed above, FIGS. 2 through 4 illustrate the first embodiment based on an 8-bit flash ADC. This can be expressed into a general form in the following equations. The number of MSB bits equal X+Z, where Z is the number of the additional bits, depending on whether noise is to be compensated. The resolution of the converted digital signal, N, equals X+Y, where Y is the number of LSB bits. In the first step of conversion, the reference voltage is divided into 2^{(X+Y)} segments for a coarse conversion. A reference voltage sub-range, in which the analog signal falls, would include 2^{Z} of the segments. Z is equal to 0, when a noise interfering with the analog signal is not compensated. Z is equal to or greater than 1, when a noise interfering with the analog signal is compensated. In the second step of conversion, the reference voltage sub-range is divided into 2^{Y} segments for a fine conversion.

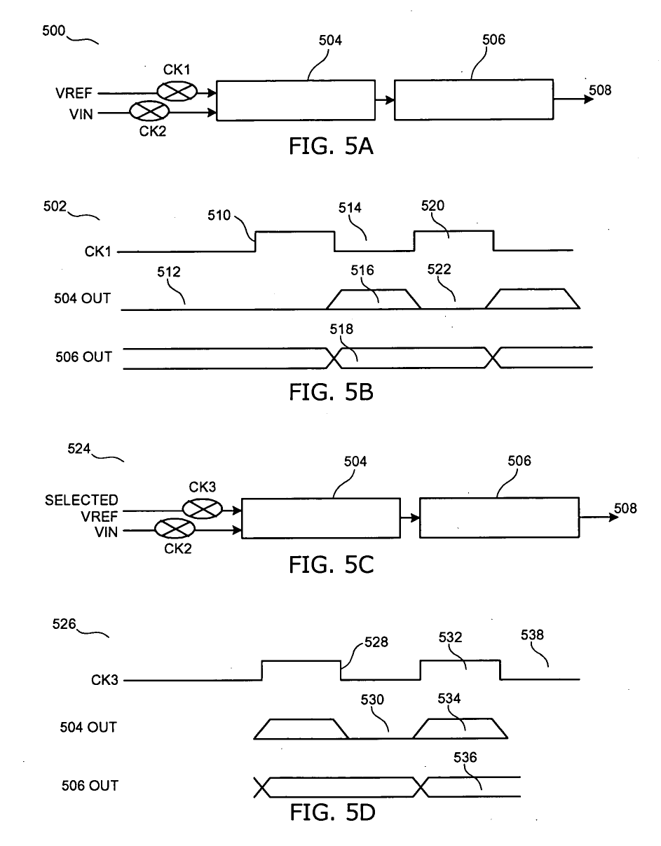

FIGS. 5A and 5B present a block diagram 500 and a timing diagram 502 of the first-step MSB conversion in accordance with one embodiment of the present invention. The block diagram 500 shows the V_{REF} and V_{IN} signals inputted to a comparator 504 as determined by clock signals CK1 and CK2 signals, respectively. The comparator 504 determines its output level and sends the output level to a latch 506, which latches an output 508 for the decoder to insure proper timing with the other MSB outputs.

The timing diagram 502 shows that the reference voltage V_{REF} is clocked into the comparator 504 at a point 510 and sampled by a sample and hold circuit controlled by the clock CK1. At the same time, the comparator auto-zeros the comparator's output signal during a period 512. The V_{IN} signal is then fed to the comparator 504 and sampled by a sample and hold circuit during a period 514. The sample of the V_{IN} signal is compared to the V_{REF} signal during a period 516. The comparator 504 output is then latched by the latch 506 during a period 518 to synchronize this output with the other MSB comparator outputs. The first-step MSB conversion then repeats itself, starting at a point 520 and a period 522 with the V_{REF} sampling and the auto-zero process.

FIGS. 5C and 5D present a block diagram 524 and a timing diagram 526 of the second-step ADC in accordance with one embodiment of the present invention. The block diagram 524 shows that the V_{REF} and V_{IN} signals are fed to a comparator 504 as determined by the clocks CK3 and CK2, respectively. The comparator 504 determines its output level and sends the output to the latch 506, which latches an output 508 for the decoder to insure proper timing with the other LSB outputs.

The timing diagram 526 shows that the V_{IN} signal is clocked into the comparator 504 at a point 528 and sampled by a sample and hold circuit controlled by the clock CK3. At the same time, the comparator auto-zeros the comparator's output signal during a period 530. The V_{REF} signal is then fed to the comparator and sampled by a sample and hold circuit during a period 532. The sample of the V_{IN} signal is compared to the V_{REF} signal during a period 534. This is performed at least one-half clock cycle later than the period 516 when the V_{IN} signal is compared to the V_{REF} in the first conversion step. The comparator 504 output is then latched by the latch 506 during a period 536 to synchronize this output with the other LSB comparator outputs. The second-step LSB conversion then repeats itself, starting at a step 538 with the V_{IN} sampling and the auto-zero process.

In this invention, the V_{IN} signal is sampled only once for using in both the first and second steps of conversions. This differs from conventional ADC architectures, where the sampled analog signal is delayed in time for different bit conversions. This creates a problem that while a sampled analog signal is delayed, the signal can be interfered by noise.

The above disclosure provides many different embodiments or examples for implementing different features of the disclosure. Specific examples of components and processes are described to help clarify the disclosure. These are, of course, merely examples and are not intended to limit the disclosure from that described in the claims. For example, while the embodiment discloses a flash ADC implementing a two-step conversion method, the invention includes three or more step conversion method.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the disclosure, as set forth in the following claims.

1. A method for converting an analog signal to a digital signal comprising:
comparing the analog signal with a plurality of reference levels, offsetting each of said reference levels by a predetermined offset value for noise compensation, dividing a reference voltage range to generate a first set of conversion bits indicating the reference level surpassed by the analog signal;
selecting a reference voltage sub-range defined by a first reference level and a second reference level, wherein the analog signal has a voltage level higher than the first reference level and lower than the second reference level;
dividing the reference voltage sub-range by a plurality of reference sub-levels;
comparing the analog signal with the reference sub-levels to generate a second set of conversion bits indicating the reference sub-level surpassed by the analog signal; and
generating the digital signal representing the analog signal based on the first set of conversion bits and the second set of conversion bits.

2. The method of claim 1 wherein the first conversion bits have X bits plus Z additional bits, the second conversion bits have Y bit, and the digital signal has N bits resolution, where X+Y=N and X, Y, Z and N are integers including zero.

3. The method of claim 2 wherein the reference voltage range is divided into 2^{(X+Z)} segments by the reference levels.

4. The method of claim 3 wherein Z is 0, when noise present with the analog signal is not compensated.

5. The method of claim 3 wherein Z is equal to or greater than 1, when noise present with the analog signal is compensated.

6. (canceled)

7. The method of claim 1 wherein the reference voltage sub-range includes 2_{Z} of the segments for calibrating the analog signal underestimated.

8. The method of claim 2 wherein the reference voltage sub-range is divided into 2^{Y} segments by the reference sub-levels.

9. The method of claim 1 wherein the analog signal is sampled only once for both the comparing the analog signal with the reference levels and the comparing the analog signal with the reference sub-levels.

10. The method of claim 1 wherein the comparing the analog signal with the reference sub-levels is performed at least one half clock cycle later than the comparing the analog signal with the reference levels.

11. A method for converting an analog signal to a digital signal comprising:
dividing a reference voltage range into a plurality of reference levels;
adding an offset value to each of the reference levels for noise compensation;
comparing the analog signal with the reference levels that is added with the offset value to generate a first set of conversion bits indicating the reference level surpassed by the analog signal;
selecting a reference voltage sub-range defined by a first reference level and a second reference level, wherein the analog signal has a voltage level higher than the first reference level plus the offset value and lower than the second reference level plus the offset value;
dividing the reference voltage sub-range by a plurality of reference sub-levels;
comparing the analog signal with the reference sub-levels to generate a second set of conversion bits indicating the reference sub-level surpassed by the analog signal; and
generating the digital signal representing the analog signal based on the first set of conversion bits and the second set of conversion bits.

12. The method of claim 11 wherein the first conversion bits have X bits plus Z additional bits, the second conversion bits have Y bit, and the digital signal has N bits resolution, where X+Y=N, and X, Y, Z and N are integers including zero.

13. The method of claim 12 wherein the reference voltage range is divided into 2^{(X+Z)} segments by the reference levels.

14. The method of claim 13 wherein Z is equal to or greater than 1.

15. The method of claim 14 wherein the reference voltage sub-range includes 2^{Z} of the segments for calibrating the analog signal underestimated.

16. The method of claim 12 wherein the reference voltage sub-range is divided into 2^{Y} segments by the reference sub-levels.

17. The method of claim 11 wherein the analog signal is sampled only once for both the comparing the analog signal with the reference levels and the comparing the analog signal with the reference sub-levels.

18. The method of claim 11 wherein the comparing the analog signal with reference sub-levels is performed at least one half clock cycle later than the comparing the analog signal with the reference levels.

19. An analog to digital converter comprising:
a first converter module connected to an analog signal input for comparing the analog signal input with a plurality of reference voltage levels to generate first conversion bits, each of the reference voltage levels having an offset value added for noise compensation and to select a reference voltage sub-range defined by a first value and a second value of the reference voltage levels, wherein the analog signal input has a voltage level higher than the first value and lower than the second value;
a second converter module, coupled to the analog signal input and the first converter module, for comparing the analog signal input with a plurality of reference sub-levels divided from the reference voltage sub-range to generate second conversion bits; and
a multiplexer, coupled to the first converter module and the second converter module, for generating a digital signal representing the analog signal input based on the first conversion bits and the second conversion bits.

20. The analog to digital converter of claim 19 wherein the first conversion bits have X bits plus Z additional bits, the second conversion bits have Y bit, and the digital signal has N bits resolution, where X+Y=N, and X, Y, Z and N are integers including zero.

21. The analog to digital converter of claim 20 wherein Z is 0, when noise present with the analog signal input is not compensated.

22. The analog to digital converter of claim 20 wherein Z is equal to or greater than 1, when noise present with the analog signal is compensated.

23. (canceled)

24. The analog to digital converter of claim 19 wherein the second conversion module comprises a reference resistive ladder for generating the reference sub-levels.

25. The analog to digital converter of claim 24 wherein the second conversion module comprises a plurality of comparators, coupled with the analog signal input and the reference resistive ladder, wherein each of the comparators receives the analog signal input and one of the reference sub-levels generated from the reference resistive ladder.

26. The analog to digital converter of claim 25 wherein the comparator outputs a high value when the analog signal input is higher than the reference sub-level, a low value when the analog signal input is lower than the reference sub-level.

27. The analog to digital converter of claim 25 wherein the second conversion module comprises at least one decoder, coupled with the converters, for decoding the high values and the low values output from the comparators into the second conversion bits.

28. The analog to digital converter of claim 19 wherein the first conversion module and the second conversion module are controlled by at least one time clock.

29. The analog to digital converter of claim 28 wherein the second conversion module operates at least one half clock cycle later than the first conversion module.
